(19) United States
(12) Patent Application Publication
(10) Pub. No.: US 2026/0271622 A1
(43) Pub. Date: Sep. 10, 2026

(54) COMPOSITION FOR CERAMIC SPEAKER, CERAMIC SPEAKER MANUFACTURING METHOD USING SAME, AND CERAMIC SPEAKER USING SAME

(71) Applicant: AMOSENSE CO.,LTD, Cheonan-si, Chungcheongnam-do (KR)

(72) Inventors: Jong-Kwan CHOI, Cheonan-si, Chungcheongnam-do (KR); Jae-Yong SONG, Cheonan-si, Chungcheongnam-do (KR); Jeong-Sang YU, Cheonan-si, Chungcheongnam-do (KR); Chang-Woo OH, Cheonan-si, Chungcheongnam-do (KR)

(73) Assignee: AMOSENSE CO.,LTD, Cheonan-si, Chungcheongnam-do (KR)

(21) Appl. No.: 19/473,787

(22) PCT Filed: Apr. 9, 2024
(86) PCT No.: PCT/KR2024/004731

§ 371 Date: Oct. 8, 2025

(30) Foreign Application Priority Data
Apr. 10, 2023 (KR) 10-2023-0046818

(51) Int. Cl. H10N 30/853; C04B 35/472; C04B 35/63; C04B 35/638; H04R 17/00; H04R 31/00; H10N 30/097

(52) U.S. Cl. CPC H10N 30/8554; C04B 35/472; C04B 35/6303; C04B 35/638; H04R 17/00; H04R 31/00; H10N 30/097; C04B 2235/3203; C04B 2235/3208; C04B 2235/3294; C04B 2235/3298; C04B 2235/6567

(57) ABSTRACT

A composition for a ceramic speaker is provided. The composition for a ceramic speaker, according to one embodiment of the present invention, comprises: ceramics; sintering aids; and oxide-based additives containing Bi₂O₃. Therefore, the present invention can be sintered at the same time as an inner electrode while being thin, has excellent piezoelectric property so as to have excellent performance when applied to a speaker, and has high permittivity.

### CROSS-REFERENCE TO RELATED APPLICATIONS

This application is the National Phase Entry of International Application No. PCT/KR2024/004731, filed on Apr. 9, 2024, which is based upon and claims priority to Korean Patent Application No. 10-2023-0046818, filed on Apr. 10, 2023, the entire contents of which are incorporated herein by reference.

### TECHNICAL FIELD

The present invention relates to a composition for a ceramic speaker, and more particularly, to a composition for a ceramic speaker, a method for manufacturing a ceramic speaker using the same, and a ceramic speaker manufactured thereby.

### BACKGROUND

Ceramics are generally sintered at high temperatures of 1,000° C. or higher, during which the volatilization of PbO makes reproduction difficult and causes environmental pollution and harmful effects on the human body. Accordingly, methods for suppressing the volatilization of PbO have been studied, one of which is to suppress the volatilization by lowering the firing temperature to 1,000° C. or less.

In addition, lowering the firing temperature of ceramics can improve cost competitiveness during production. One representative method for lowering the sintering temperature of ceramics is to induce low-temperature sintering by adding glass frits having a low melting point and oxides as sintering aids to form a liquid phase.

In the conventional method, densification of ceramics is promoted at the early stage of sintering, thereby enabling sintering at a low temperature; however, there is a drawback in that dielectric and piezoelectric properties are deteriorated. Therefore, it is required not only to lower the sintering temperature but also to minimize the degradation of the properties, and research and development on sintering aids are needed to solve such problems.

### SUMMARY OF THE INVENTION

The present invention has been devised to solve the above-described conventional problems, and an object of the present invention is to provide a composition for a ceramic speaker that can be made into a thin film and can be co-sintered with an internal electrode, a method for manufacturing a ceramic speaker using the same, and a ceramic speaker manufactured thereby.

Another object of the present invention is to provide a composition for a ceramic speaker that exhibits excellent piezoelectric properties, thereby achieving superior performance when applied to a speaker, and has high permittivity, as well as a method for manufacturing a ceramic speaker using the same and a ceramic speaker manufactured thereby.

To solve the above-described problems, the present invention provides a composition for a ceramic speaker including ceramics, a sintering aid, and an oxide-based additive comprising Bi₂O₃.

According to one embodiment of the present invention, the ceramics may include a composition represented by the following Chemical Formula 1:

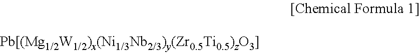

where x, y, and z are each independently a rational number from 0.01 to 0.99, and x+y+z=1.

In addition, the oxide-based additive may be included in an amount of 0.3 to 1.3 parts by weight based on 100 parts by weight of the ceramics.

In addition, the sintering aid may include at least one selected from the group consisting of Li₂CO₃, CaCO₃, PbO, and CuO.

In addition, the sintering aid may be included in an amount of 0.2 to 1.5 parts by weight based on 100 parts by weight of the ceramics.

In addition, the present invention provides a method for manufacturing a ceramic speaker including a step of sintering the above-described composition for a ceramic speaker at a temperature of 880 to 960° C.

According to one embodiment of the present invention, the sintering step may be performed for 1 to 3 hours.

In addition, the composition for a ceramic speaker may further include a binder, and the method may further include a step of removing the binder before the sintering step.

In addition, the binder removal step may be performed at a temperature of 240 to 300° C.

In addition, the present invention provides a ceramic speaker formed using the above-described composition for a ceramic speaker.

According to one embodiment of the present invention, the ceramic speaker may have a piezoelectric constant d₃₃ of 600 pC/N or more.

The composition for a ceramic speaker, the method for manufacturing a ceramic speaker using the same, and the ceramic speaker manufactured thereby according to the present invention can be made into a thin film and can be co-sintered with an internal electrode, and have excellent piezoelectric properties, thereby exhibiting superior performance when applied to a speaker.

### DETAILED DESCRIPTION

Hereinafter, exemplary embodiments of the present invention will be described in detail so that those of ordinary skill in the art can readily implement the present invention. The present invention may be embodied in many different forms and is not limited to the embodiments set forth herein.

The composition for a ceramic speaker according to the present invention is implemented to include ceramics; sintering aids; and oxide-based additives containing Bi₂O₃.

Hereinafter, each component of the composition for a ceramic speaker according to the present invention will be described in detail.

First, the ceramics will be described.

The ceramics may include one of known lead-based piezoelectric ceramic components and lead-free piezoelectric ceramic components, a mixture thereof, or an alloy thereof. Preferably, the ceramics may include at least one selected from the group consisting of lead zirconate titanate (PZT), lead magnesium niobate (PMN), lead nickel niobate (PNN), lead titanate (PT), lead magnesium tungstate (PMW), PNN-PZT, PMN-PT, PMW-PZT, BS-PT, and lanthanum-doped lead zirconate titanate (PLZT). More preferably, the ceramics may include a mixture or an alloy of at least one selected from the group consisting of Pb(Ti, Zr)O₃, Pb(Mg_{1/3}Nb_{2/3})O₃, Pb(Mg_{1/3}Ta_{2/3})O₃, Pb(Ni_{1/3}Nb_{2/3})O₃, Pb(Mn_{1/3}Ta_{2/3})O₃, Pb(Mn_{1/3}Sb_{2/3})O₃, Pb(Zn_{1/3}Nb_{2/3})O₃, Pb(Zn_{1/3}Ta_{2/3})O₃, Pb(Mn_{1/3}Nb_{2/3})O₃, Pb(Co_{1/3}Sb_{2/3})O₃, Pb(Zn_{1/3}Nb_{2/3})O₃, Pb(Co_{1/3}Nb_{2/3})O₃, Pb(Fe_{1/3}Sb_{2/3})O₃, Pb(Fe_{1/3}Nb_{2/3})O₃, Pb(Mn_{1/3}Bi_{2/3})O₃, Pb(Mg_{1/3}Nb_{2/3})O₃, Pb(Mg_{1/3}Ta_{2/3})O₃, Pb(Ni_{1/3}Nb_{2/3})O₃, Pb(Mn_{1/3}Ta_{2/3})O₃, Pb(Mn_{1/3}Sb_{2/3})O₃, Pb(Zn_{1/3}Nb_{2/3})O₃, Pb(Zn_{1/3}Ta_{2/3})O₃, Pb(Mn_{1/3}Nb_{2/3})O₃, Pb(Co_{1/3}Sb_{2/3})O₃, Pb(Zn_{1/3}Nb_{2/3})O₃, Pb(Co_{1/3}Nb_{2/3})O₃, Pb(Fe_{1/3}Sb_{2/3})O₃, Pb(Fe_{1/3}Nb_{2/3})O₃, Pb(Mn_{1/3}Bi_{2/3})O₃, Pb(Cd_{1/2}W_{1/2})O₃, Pb(Mg_{1/2}W_{1/2})O₃, Pb(Co_{1/2}W_{1/2})O₃, Pb(Ni_{1/2}W_{1/2})O₃, Pb(Mn_{1/2}W_{1/2})O₃, Pb(Ca_{1/2}W_{1/2})O₃, Pb(Fe_{2/3}W_{1/3})O₃, Pb(Mn_{2/3}W_{1/3})O₃, La(Mg_{1/2}Ti_{1/2})O₃, Nd(Mg_{1/2}Ti_{1/2})O₃, Pb(Li_{1/4}Nb_{3/4})O₃, Pb(Cu_{1/4}Nb_{3/4})O₃, Pb(Li_{1/4}Sb_{3/4})O₃, and Pb(Mg_{1/2}W_{1/2})O₃—Pb(Ni_{1/3}Nb_{2/3})O₃—(Zr_{0.5}Ti_{0.5})O₃. Still more preferably, the ceramics may include a composition represented by Pb[(Mg_{1/2}W_{1/2})ₓ(Ni_{1/3}Nb_{2/3})_{y}(Zr_{0.5}Ti_{0.5})_{z}O₃], where x, y, and z are each independently a rational number from 0.01 to 0.99, and x+y+z=1, and most preferably, may include a composition represented by Pb[(Mg_{1/2}W_{1/2})_{0.03}(Ni_{1/3}Nb_{2/3})_{0.09}(Zr_{0.5}Ti_{0.5})_{0.88}O₃], which is more advantageous for achieving the object of the present invention.

In addition, the sintering aid serves to assist the sintering of the ceramics, and any sintering aid that can be conventionally used in the art may be employed without limitation. Preferably, the sintering aid may include at least one selected from the group consisting of Li₂CO₃, CaCO₃, PbO, and CuO, and more preferably, may include one or more of Li₂CO₃ and CaCO₃, which is more advantageous for achieving the object of the present invention.

In this case, the sintering aid may be included in an amount of 0.2 to 1.5 parts by weight based on 100 parts by weight of the ceramics, and preferably in an amount of 0.3 to 1.0 parts by weight. If the amount of the sintering aid is less than 0.2 parts by weight or exceeds 1.5 parts by weight based on 100 parts by weight of the ceramics, the piezoelectric property may be deteriorated.

In addition, the oxide-based additive can lower the sintering temperature of the ceramics, thereby enabling co-sintering with an internal electrode, and serves to provide excellent piezoelectric properties so that superior performance can be achieved when applied to a speaker.

The oxide-based additive may include Bi₂O₃ as described above and may further include Sb₂O₅. However, it is preferable that the oxide-based additive includes only Bi₂O₃, which can lower the sintering temperature of the ceramics, thereby enabling co-sintering with an internal electrode, and is more advantageous in that excellent piezoelectric properties can be achieved, resulting in superior performance when applied to a speaker. Meanwhile, when Sb₂O₅ is further included, the sinterability may be relatively degraded compared to when it is not included, thereby lowering the piezoelectric property and permittivity. Therefore, the oxide-based additive may not include Sb₂O₅.

In this case, the oxide-based additive may be included in an amount of 0.3 to 1.3 parts by weight based on 100 parts by weight of the ceramics, and preferably in an amount of 0.5 to 1 parts by weight. If the oxide-based additive is less than 0.3 parts by weight based on 100 parts by weight of the ceramics, the sinterability may be poor, and the piezoelectric property and permittivity may be low. On the other hand, if the oxide-based additive exceeds 1.3 parts by weight based on 100 parts by weight of the ceramics, the piezoelectric property may be reduced.

Meanwhile, the composition for a ceramic speaker may further include a solvent.

The solvent may be a known solvent that facilitates the dispersion of the above-described ceramics, sintering aid, and oxide-based additive, and does not interfere with the dissolution of a binder when the binder is included. For example, the solvent may be a mixed solvent including one or more organic solvents such as toluene and ethanol.

In addition, the composition for a ceramic speaker may further include, in addition to the components described above, known binders, plasticizers, dispersants, or defoaming agents, and the present invention is not particularly limited thereto.

Non-limiting examples of the plasticizer may include phthalate esters such as dioctyl-4,5-epoxy-hexahydrophthalate, tris-(octoxycarbonylethyl)isocyanurate, tristearin, epoxidized soybean oil, and other similar compounds, or mixtures thereof.

In addition, the present invention provides a method for manufacturing a ceramic speaker, the method including a step of sintering the above-described composition for a ceramic speaker.

The sintering step may be performed at a temperature of 880 to 960° C., preferably at a temperature of 900 to 940° C., and more preferably at a temperature of 910 to 930° C. If the sintering temperature is lower than 880° C., sintering may not proceed to a desired level, resulting in low piezoelectric property and permittivity. If the sintering temperature exceeds 960° C., the connectivity of the internal electrode may deteriorate during co-sintering with the internal electrode, thereby lowering the permittivity and sound pressure characteristics.

In addition, the sintering step may be performed for 1 to 3 hours, preferably for 1.5 to 2.5 hours. If the sintering step is performed for less than 1 hour, sintering may not proceed to a desired level, resulting in low piezoelectric property and permittivity. If the sintering step is performed for more than 3 hours, reliability degradation and an increase in permittivity may occur.

In this case, the sintering step may be performed such that the composition for a ceramic speaker and an internal electrode are co-sintered, whereby the process can be simplified while simultaneously exhibiting excellent piezoelectric property and permittivity.

Meanwhile, according to one embodiment of the present invention, the composition for a ceramic speaker may further include a binder, and the method for manufacturing a ceramic speaker according to the present invention may further include a step of removing the binder before the sintering step.

The binder removal step may be performed under conditions that can be conventionally used in the art, and preferably at a temperature of 240 to 300° C., and more preferably at a temperature of 260 to 280° C.

Meanwhile, the method for manufacturing a ceramic speaker according to the present invention may further include, before the binder removal step, a step of forming the above-described composition for a ceramic speaker into a sheet, and a step of laminating the composition for a ceramic speaker formed into a sheet.

In this case, the step of forming into a sheet may be performed without limitation by any sheet-forming method conventionally used in the art, and preferably by a casting or pressing method, but is not limited thereto.

In addition, the laminating step may be performed by any method conventionally used in the art, and therefore, the present invention is not particularly limited thereto.

Meanwhile, the present invention provides a ceramic speaker formed using the above-described composition for a ceramic speaker.

In this case, the ceramic speaker may have a piezoelectric constant d₃₃ of 600 pC/N or more, preferably 610 pC/N or more, more preferably 615 pC/N or more, and most preferably 619 pC/N or more.

### EXAMPLES

The present invention will be described in more detail through the following examples, but the following examples are not intended to limit the scope of the present invention, which should be construed to aid understanding of the present invention.

### EXAMPLES

### Example 1

First, a composition for a ceramic speaker was prepared by including 0.6 parts by weight of an oxide-based additive of Bi₂O₃, 0.7 parts by weight of a sintering aid containing Li₂CO₃ and CaCO₃ in a weight ratio of 1:1, and 6.5 parts by weight of a binder, based on 100 parts by weight of ceramics having an average particle size of 0.75 μm and a composition represented by Pb[(Mg_{1/2}W_{1/2})_{0.03}(Ni_{1/3}Nb_{2/3})_{0.09}(Zr_{0.5}Ti_{0.5})_{0.88}O₃].

The prepared composition for a ceramic speaker was formed into a sheet having a thickness of 30 μm by a tape casting method, and several sheets were laminated to obtain a total thickness of 1.0 mm. The laminated body was then heated in a furnace at a heating rate of 0.2° C./min and heat-treated at 270° C. for 3 hours to remove the binder, followed by heating at a heating rate of 3° C./min and maintaining the temperature at 920° C. for 2 hours to perform sintering. After the sintering step, the body was cooled under natural cooling conditions to obtain a sintered ceramic.

### Examples 2 to 7 and Comparative Examples 1 to 2

Ceramics were manufactured in the same manner as in Example 1, except that the material type and content of the oxide-based additive were changed, to produce sintered ceramics as shown in Tables 1 and 2 below.

### Experimental Example

For each of the sintered ceramics manufactured according to the examples and comparative examples, the following physical properties were evaluated and are shown in Tables 1 and 2 below.

### 1. Measurement of Permittivity

For each of the sintered ceramics manufactured according to the examples and comparative examples, an external electrode was applied, and the capacitance of the product was measured using a capacitance meter, from which the permittivity was calculated.

### 2. Measurement of Piezoelectric Constant d₃₃

For each of the sintered ceramics manufactured according to the examples and comparative examples, the piezoelectric constant d₃₃ was measured using a d₃₃ meter.

TABLE 1

| | | Example | Example | Example | Example | Example |
|---|---|---|---|---|---|---|
| Classification | | 1 | 2 | 3 | 4 | 5 |
| Oxide-based | Material type | Bi₂O₃ | Bi₂O₃ | Bi₂O₃ | Bi₂O₃ | Bi₂O₃ |
| additive | [symbol] ontent (parts by weight) | 0.6 | 0.5 | 0.8 | 1 | 1.5 |

| | | | | | |
|---|---|---|---|---|---|
| Permittivity (F/m) | 2523 | 2472 | 2604 | 2640 | 2292 |
| Piezoelectric constant d₃₃ (pC/N) | 649 | 655 | 647 | 620 | 588 |

[symbol]

indicates data missing or illegible when filed

TABLE 3

| | | Example | Example | Comparative | Comparative |
|---|---|---|---|---|---|
| Classification | | 6 | 7 | Example 1 | Example 2 |
| Oxide-based | Material type | Bi₂O₃/ | Bi₂O₃/ | Bi₂O₃ | Sb₂O₅ |
| additive | | Sb₂O₅ | Sb₂O₅ | | |
| | [symbol] ntent (parts | 0.6/0.2 | 0.6/0.3 | 0 | 0.6 |
| | by weight) | | | | |

| | | | | |
|---|---|---|---|---|
| Permittivity (F/m) | 2030 | 1248 | 995 | 462 |
| Piezoelectric constant d₃₃ (pC/N) | 595 | 417 | 282 | 79 |

[symbol]

indicates data missing or illegible when filed

As shown in Tables 1 to 3, Examples 1 to 4, which satisfy all the conditions regarding the material type and content of the oxide-based additive according to the present invention, were found to simultaneously exhibit significantly superior permittivity and piezoelectric properties (piezoelectric constant d₃₃) compared with Examples 5 to 7 and Comparative Examples 1 and 2, which fail to satisfy at least one of these conditions.

Specifically, it can be confirmed that Examples 1 to 4, which satisfy the content range of Bi₂O₃ according to the present invention, exhibit significantly superior permittivity and piezoelectric properties compared with Example 5, in which the content of Bi₂O₃ exceeds the defined range.

In addition, it can be confirmed that Example 1, in which the oxide-based additive according to the present invention does not include Sb₂O₅, exhibits significantly superior permittivity and piezoelectric properties compared with Examples 6 and 7, in which the oxide-based additive includes Sb₂O₅. In particular, it was observed that as the content of Sb₂O₅ increases, the permittivity and piezoelectric properties gradually decrease.

It can also be confirmed that Examples 1 to 4, which satisfy the content range of Bi₂O₃ according to the present invention, exhibit significantly superior permittivity and piezoelectric properties compared with Comparative Example 1, in which the content of Bi₂O₃ is below the defined range.

Furthermore, it can be confirmed that Example 1, in which the oxide-based additive according to the present invention includes Bi₂O₃, exhibits significantly superior permittivity and piezoelectric properties compared with Comparative Example 2, in which the oxide-based additive does not include Bi₂O₃.

Although exemplary embodiments of the present invention have been described above, the scope of the present invention is not limited to the embodiments set forth herein. Those skilled in the art who understand the spirit of the present invention may readily propose other embodiments by adding, modifying, deleting, or supplementing components within the scope of the present invention, and such embodiments should also be regarded as falling within the scope of the present invention.

1. A composition for a ceramic speaker, comprising:
ceramics;
a sintering aid; and
an oxide-based additive comprising Bi₂O₃.

2. The composition for a ceramic speaker according to claim 1, wherein the ceramics comprise a composition represented by the following Chemical Formula 1: 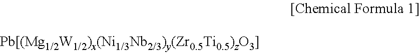
where x, y, and z are each independently a rational number from 0.01 to 0.99, and x+y+z=1.

3. The composition for a ceramic speaker according to claim 1, wherein the oxide-based additive is included in an amount of 0.3 to 1.3 parts by weight based on 100 parts by weight of the ceramics.

4. The composition for a ceramic speaker according to claim 1, wherein the sintering aid comprises at least one selected from the group consisting of Li₂CO₃, CaCO₃, PbO, and CuO.

5. The composition for a ceramic speaker according to claim 1, wherein the sintering aid is included in an amount of 0.2 to 1.5 parts by weight based on 100 parts by weight of the ceramics.

6. A method for manufacturing a ceramic speaker comprising a step of sintering the composition for a ceramic speaker according to claim 1 at a temperature of 880 to 960° C.

7. The method for manufacturing a ceramic speaker according to claim 6, wherein the sintering step is performed for 1 to 3 hours.

8. The method for manufacturing a ceramic speaker according to claim 6,
wherein the composition for a ceramic speaker further comprises a binder,
and the method further comprises a step of removing the binder before the sintering step.

9. The method for manufacturing a ceramic speaker according to claim 8, wherein the binder removal step is performed at a temperature of 240 to 300° C.

10. A ceramic speaker formed using the composition for a ceramic speaker according to claim 1.

11. The ceramic speaker according to claim 10, wherein the ceramic speaker has a piezoelectric constant d₃₃ of 600 pC/N or more.
